(19) United States
(12) Patent Application Publication
(10) Pub. No.: US 2008/0318425 A1
(43) Pub. Date: Dec. 25, 2008

(54) SEMICONDUCTOR DEVICE PRODUCTION METHOD

(76) Inventor: Naoaki SATO, Toyama (JP)

Correspondence Address: MCDERMOTT WILL & EMERY LLP, 600 13TH STREET, NW, WASHINGTON, DC, 20005-3096, US

(21) Appl. No.: 12/125,535

(22) Filed: May 22, 2008

(30) Foreign Application Priority Data
Jun. 25, 2007 (JP) 2007-165790

(51) Int. Cl. H01L 21/461

(52) U.S. Cl. 438/692; 257/E21.483

(57) ABSTRACT

The purpose of the present invention is to stabilize the polishing film thickness during the overpolishing following the removal of barrier metal in Cu-CMP (chemical mechanical polishing). To this end, a table in which the relationship between wire perimeter and overpolishing process polishing rate is created. The polishing time is calculated based on the wire perimeter in determining the overpolishing time after the removal of barrier metal in Cu-CMP to stabilize the overpolishing film thickness.

### BACKGROUND OF THE INVENTION

The present invention relates to a semiconductor device production method and particularly to a technique for improvement in the process capability index of a chemical mechanical polishing (CMP) process.

### DESCRIPTION OF THE RELATED ART

As semiconductor devices are more integrated and downsized, progress has been made in multilayer wiring, Cu (copper) and low dielectric constant (low-k) wiring materials, and small-pitched structures. CMP techniques have been developed for supporting this progress. The CMP is a polishing technique in which slurry consisting of polishing powder and a chemical solution is supplied between the rotating polishing pad and surface to be polished of a semiconductor wafer (simply termed “wafer” hereafter).

Particularly, Cu-CMP is important for realizing the Cu damocene process that is dominantly used in Cu wiring process for semiconductor devices complying with 0.13 μm or smaller design rules. The Cu-CMP is in charge of removal of unnecessary Cu other than the wiring pattern and barrier metals and overpolishing so that the polished, remaining film has a desired film thickness. The Cu-CMP for forming a wiring structure according to device design in the Cu damocene process is essential.

In the above technique, the polishing should be stopped in a proper time to control the film thickness with high accuracy. It will be fine if there is no variation in the apparatus or fluctuation in the polishing rate resulting from the film nature. However, this is not in practice. In the CMP, a blanket wafer (expendable wafer) is polished before polishing actual product wafers to determine a reference polishing rate of the CMP apparatus used. The reference polishing rate is determined on a regular basis so that the polishing time can be calculated based on a reference polishing rate value as accurate as possible before product wafers are polished.

There is a demand for an APC (advanced process control) system technique for calculating the polishing rate in an efficient and accurate manner. The APC system is a technique for measuring the processing results of processes and controlling the processes using the obtained data in fields involving many complex processes and a variety of variables. A related technique is disclosed in the Japanese Laid-Open Patent Application No. 2002-141319.

This literature discloses a technique for measuring the film thickness of a patterned wafer of a product type (indicating the type of a wafer to be polished hereafter) A before/after polishing, estimating the polishing rate of a blanket wafer (no-pattern wafer) from the result, and calculating the polishing time of a wafer of a product type B (a patterned wafer), whereby the polishing time corresponding to the polishing rate varied by product type is adjusted to control the film thickness with high accuracy.

### SUMMARY OF THE INVENTION

However, the inventor of the present invention found that the technique disclosed in the above literature has the following problems.

After the barrier metal is polished by Cu-CMP, the wafer surface to be overpolished has Cu wiring, barrier metal, and interlayer insulating film. They are present at different ratios depending on the product type/layer. This means that different films are to be polished depending on the product type. Therefore, the polishing rate varies by product type.

When an APC system is used to control the overpolishing time and the calculated values of polishing rate are improper, there is an increasing risk of excessive or insufficient polishing, reducing product yields. Therefore, it is significantly important that differences in the polishing rate among the product types/layers are incorporated in the polishing rate calculation expressions in the APC system.

In the prior art, the relationship between polishing time and polishing film thickness is obtained through experiments made in advance and differences in the polishing rate among the product types/layers are incorporated in the polishing rate calculation expressions in the APC system. However, this method problematically requires long term experiments to obtain data in advance and high cost.

Furthermore, recent demands for high-mix low-volume production require frequent replacement of product types in small lots. Therefore, experiments on a case-by-case basis further increase semiconductor development costs.

The purpose of the present invention is to facilitate the determination of polishing rate or polishing time of the overpolishing after the removal of barrier metal in Cu-CMP.

The semiconductor device production method of the present invention is characterized by calculating the polishing time based on the wire perimeter in determining the overpolishing time after the removal of barrier metal in Cu-CMP so as to stabilize the overpolishing film thickness.

Furthermore, the production method is characterized by having the wire perimeter as a variable in a polishing time calculation expression in an APC system for determining the polishing time so as to stabilize the overpolishing film thickness.

Furthermore, the production method estimates the polishing rate from monitoring data obtained by a film thickness measuring apparatus in the case of using an APC system so as to reduce measurement costs.

The present invention allows for improvement in the accuracy of the estimated polishing rate and polishing time in processing a variety of product types/layers and highly accurate control over the film thickness in a semiconductor device production method.

### BRIEF DESCRIPTION OF THE DRAWINGS

FIG. 1 is a schematic illustration showing the structure of a substrate processing apparatus in Embodiment 1 of the present invention.

FIG. 2 is a schematic perspective view showing the core structure of the polishing unit in Embodiment 1.

FIG. 3 is a graphical representation showing the relationship between wire perimeter and polishing rate.

FIG. 4 is a flowchart of the semiconductor production method of Embodiment 1.

FIG. 5 is a schematic chart showing the process control system configuration in Embodiment 2 of the present invention.

FIG. 6 is a flowchart of the semiconductor production method of Embodiment 2.

FIG. 7 is a schematic chart showing the process control system configuration in Embodiment 3 of the present invention.

FIG. 8 is a graphical representation showing the relationship between the platen rotation torque current and the polishing rate in Embodiment 3.

FIG. 9 is a flowchart of the semiconductor production method of Embodiment 3.

### DETAILED DESCRIPTION OF PREFERRED EMBODIMENTS

Embodiments of the present invention are described hereafter with reference to the drawings. In the following embodiments, the present invention is realized in forming copper wiring on a semiconductor wafer (simply termed the wafer hereafter). In the following embodiments, the chemical mechanical polishing (CMP) includes polishing using standard polishing pads along with floating polishing powder, fixed polishing powder, and something in-between.

### Embodiment 1

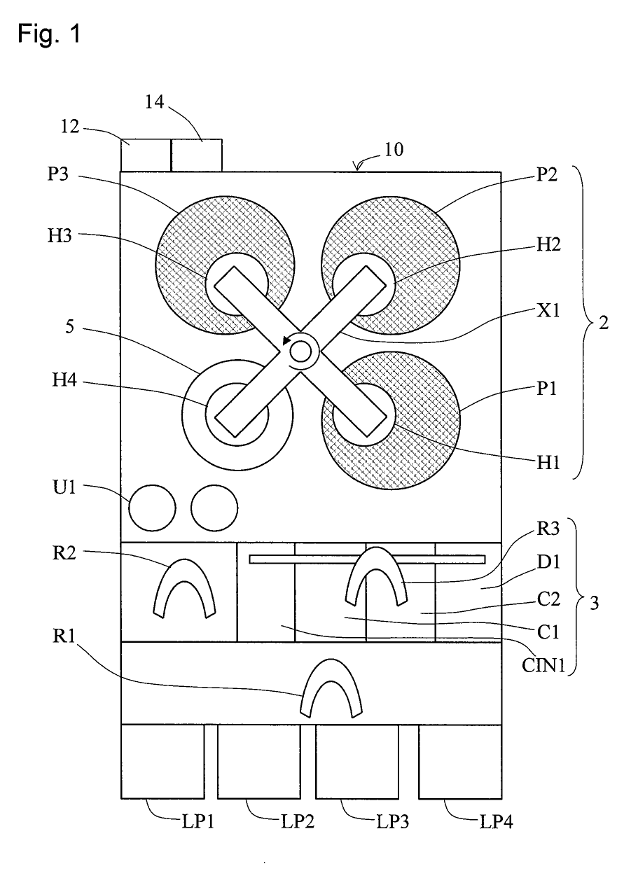

FIG. 1 is a schematic illustration showing the structure of a substrate processing apparatus in Embodiment 1 of the present invention.

As shown in FIG. 1, a substrate processing apparatus 10 of this embodiment comprises a polishing unit 2 for polishing wafers and a cleaning unit 3 for cleaning wafers polished by the polishing unit 2. The cleaning unit 3 is adjacent to the polishing unit 2. A wet robot R2 for transferring wafers is adjacent both to the polishing unit 2 and to the cleaning unit 3.

A dry robot R1 movable along the wet robot R2 and cleaning unit 3 is placed on the opposite side of the cleaning unit 3 and wet robot R2 of the polishing unit 2. Furthermore, multiple load ports LP1, LP2, LP3, and LP4 where containers with wafers therein such as FOUPs (front opening unified pods) are detachably placed on the opposite side of the dry robot R1 to the cleaning unit 3 and wet robot R2.

The dry robot R1 retrieves wafers from the containers placed on the load ports LP1 to LP4 and transfers them to the wet robot R2. Furthermore, the dry robot R1 retrieves wafers from a drying unit D1, described later, and transfers them in the containers placed on the load ports LP1 to LP4.

The wet robot R2 transfers the wafers given by the dry robot R1 to the polishing unit 2 and transfers wafers polished at the polishing unit 2 to the cleaning unit 3. The cleaning unit 3 receives wafers from the wet robot R2 at a cleaning unit receiving unit CIN1. Wafers at the cleaning unit receiving unit CIN1 are transferred by a robot R3. Cleaning and drying processes are performed at a first cleaning unit C1, a second cleaning unit C2, and a drying unit D1 in this order.

The polishing unit 2 where wafers to be processed are placed in sequence comprises three platens P1, P2, and P3 that polish the metal films (here, a TaN adhesion layer, Ta barrier metal, and Cu film) on a wafer in a phased manner. In the substrate processing apparatus 10, the first polishing platen P1 polishes the Cu film partway. Subsequently, the second polishing platen P2 polishes the Cu film to the interface with the barrier metal. The third polishing platen P3 polishes the barrier metal and adhesion layer, removing the barrier metal and performing the overpolishing.

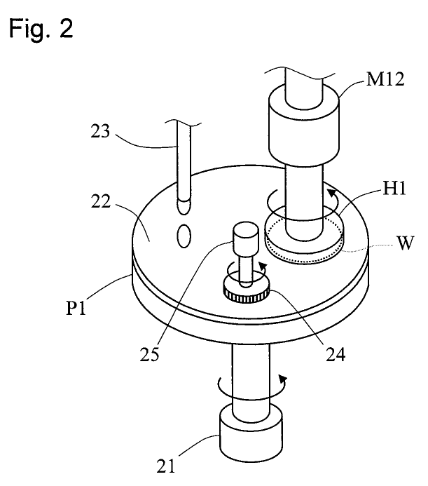

FIG. 2 is a schematic perspective view showing the core structure of the polishing unit 2 in this embodiment. FIG. 2 shows a head H1 on the first polishing platen P1. The head H1 can be rotated about the center axis by a motor M12.

As shown in FIG. 2, the first polishing platen P1 can be rotated about the center axis by a motor 21. On the first polishing platen P1 provided is a polishing pad 22 made of porous synthetic resin or non-woven cloth. A slurry arm 23 for feeding polishing slurry and a conditioner 24 for conditioning the polishing pad 22 are provided on the polishing pad 22. The conditioner 24 is rotated by a motor 25 in a plane parallel to the surface of the polishing pad 22 and vertically moved in relation to the polishing platen P1. The polishing pad 22 is conditioned for every one or several wafers being polished by contacting the conditioner 24.

For polishing and cleaning wafers in the substrate processing apparatus 10, first, an FOUP containing multiple (for example 25) wafers to be processed are placed on any load port (for example the load port LP2). Once the FOUP is placed, the dry robot R1 retrieves the first wafer W1 from the FOUP based on instructions from a transfer control unit 14.

The dry robot R1 moves to face the wet robot R2 while holding the wafer W1. The wet robot R2 receives the wafer W1 from the dry robot R1 and places the wafer W1 on a pre-polishing wafer reverse unit U1 at the polishing unit 2 based on instructions from the transfer control unit 14. It is not necessary for the dry robot 2 to receive wafers directly from the dry robot R1. A temporal wafer waiting station can be used.

Subsequently, the wafer W1 is reversed on the pre-polishing wafer reverse unit U1 and transferred to a load/unload unit 5 based on instructions from the transfer control unit 14. In this instance, one of the heads H1 to H4 is on standby above the load/unload unit 5. In this case, the head H1 is on standby.

After the wafer W1 on the pre-polishing wafer reverse unit U1 is transferred to the load/unload unit 5, the next wafer W2 is transferred from the FOUP to the pre-polishing wafer reverse unit U1.

After the wafer W1 is placed on the load/unload unit 5, the head H1 moves down and holds the wafer W1 by suction on the underside based on instructions from the transfer control unit 14. After the wafer W1 is held by suction, the transfer control unit 14 moves the head H1 up and rotates a rotary head mechanism X1 about the rotation axis by 90 degrees. Then, the head H1 moves to above the first polishing platen P1. Then, the transfer control unit 14 provides notification to a polishing control unit 12 that the transfer of a wafer to the first polishing platen P1 is completed.

Reaching above the first platen P1, the head H1 moves down to press the surface to be polished of the wafer W1 against the polishing pad 22 (see FIG. 2) on the first polishing platen P1 with a specific polishing pressure based on instructions from the polishing control unit 12. Then, the polishing control unit 12 rotates the first polishing platen P1 and head H1 while feeding polishing slurry from the slurry arm 23 (see FIG. 2), whereby the copper film on the surface of the wafer W1 is polished partway.

The end of polishing is detected by a known technique such as an eddy current end-of-polishing detection mechanism. When the polishing by the first polishing platen P1 is completed, the polishing control unit 12 instructs an unshown superpure water feeder to feed superpure water to the surface of the first polishing platen P1 to remove the polishing slurry on the surface of the wafer W1.

In parallel to the polishing of the wafer W1 by the first polishing platen P1, the transfer control unit 14 instructs the pre-polishing wafer reverse unit U1 to transfer the wafer W2 to the load/unload unit 5. After the wafer W2 is placed on the load/unload unit 5, the head H2 moves down to hold the wafer W2 by suction on the underside in the same manner as described above. Meanwhile, after the wafer W2 on the pre-polishing wafer reverse unit U1 is transferred to the load/unload unit 5, the next wafer W3 is transferred to the pre-polishing wafer reverse unit U1.

When the polishing by the first polishing platen P1 is completed, the polishing control unit 12 provides notification to the transfer control unit 14 accordingly. If the head H2 has held the wafer W2 by suction, the transfer control unit 14 moves the heads H1 and H2 up and rotates the rotary head mechanism X1 about the rotation axis by 90 degrees. Then, the head H1 moves to above the second polishing platen P2 and the head H2 moves to above the first polishing platen P1, afterwhich the transfer control unit 14 provides notification to the polishing control unit 12 that the wafer transfer is completed.

Reaching above the second polishing platen P2, the head H1 moves down and presses the surface to be polished of the wafer W1 against the polishing pad 22 (see FIG. 2) on the second polishing platen P2 with a specific polishing pressure based on instructions from the polishing control unit 12. Then, the polishing control unit 12 rotates the second polishing platen P2 and head H1 while feeding polishing slurry from the slurry arm 23 (see FIG. 2), completely removing the copper film form the surface of the wafer W1.

The end of polishing is detected by a known technique, for example by moving the head H2 up, illuminating the wafer surface with a laser, and detecting changes in the reflection intensity. When the polishing by the second polishing platen P2 is completed, the polishing control unit 12 instructs an unshown superpure water feeder to feed superpure water to the surface of the second polishing platen P2 to remove the polishing slurry.

In parallel to the polishing of the wafer W1 by the second polishing platen P2, the first polishing platen P1 polishes the wafer W2 based on instructions from the polishing control unit 12. The transfer control unit 14 instructs the pre-polishing wafer reverse unit U1 to transfer the wafer W3 to the load/unload unit 5. When the wafer W3 is placed on the load/unload unit 5, the head H3 moves down and holds the wafer W3 by suction on the underside in the same manner as described above. Meanwhile, after the wafer W3 on the pre-polishing wafer reverse unit U1 is transferred to the load/unload unit 5, the next wafer W4 is transferred to the pre-polishing wafer reverse unit U1.

When the polishing by the first and second polishing platens P1 and P2 is completed and the head H3 has held the wafer H3 by suction, the polishing control unit 12 moves the heads H1, H2, and H3 up and rotates the rotary head mechanism X1 about the rotation axis by 90 degrees. Then, the head H1 moves to above the third polishing platen P3, the head H2 moves to above the second polishing platen P2, and the head H3 moves to above the first polishing platen P1. Then, the transfer control unit 14 provides notification to the polishing control unit 12 that the wafer transfer is completed.

Reaching above the third polishing platen P3, the head H1 moves down and presses the surface to be polished of the wafer W1 against the polishing pad 22 (see FIG. 2) on the third polishing platen P3 with a specific polishing pressure based on instructions from the polishing control unit 12. Then, the polishing control unit 12 rotates the third polishing platen P3 and head H1 while feeding polishing slurry from the slurry arm 23 (see FIG. 2), whereby the barrier metal and adhesion layer on the surface of the wafer W1 are completely removed.

In the polishing process, overpolishing is performed to completely remove the metal film on the surface of the wafer W1 (the overpolishing process is referred to as the polishing step in the present invention). The removal of barrier metal and adhesion layer on the surface of the wafer W1 can be detected by a known technique, for example by illuminating the wafer surface with a laser and detecting changes in the reflection intensity. However, this technique is not used to detect the end of polishing in the overpolishing. Furthermore, when the polishing is performed for a fixed time period, the polishing film thickness varies depending on product types (the types of wafers to be polished; the same is applied hereafter) and layers.

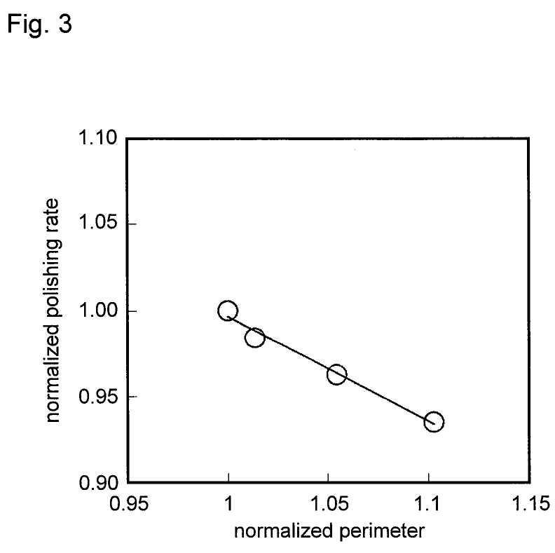

The present inventor found that the differences among the product types result from the wire perimeter. FIG. 3 shows the wire perimeter and the overpolishing process polishing rate. In FIG. 3, the ordinate and abscissa have normalized scales. It is understood from FIG. 3 that the overpolishing process polishing rate decreases as the wire perimeter increases. As the wire perimeter increases, a larger area of barrier metal having a high mechanical strength is to be polished and therefore the polishing rate decreases. It was found that the differences in the polishing rate cause differences in the overpolishing film thickness among the product types/layers.

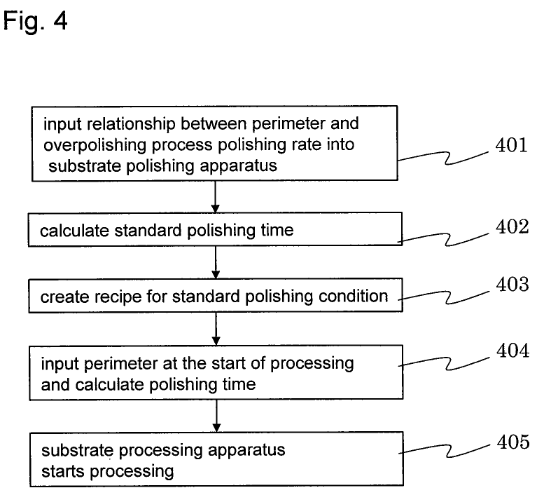

Based on the above finding, the present embodiment has a function to automatically adjust the polishing condition by including the wire perimeter in input items for the processing conditions of each platen. FIG. 4 shows a flowchart of the production method of this embodiment.

In the prior art semiconductor production apparatus including a substrate polishing apparatus, processing conditions are stored in the apparatus as a recipe. The operation setting values and operation times of components of the core structure shown in FIG. 2 are input in the recipe for the substrate polishing apparatus. More specifically, the platen rotation number, polishing head rotation number, polishing head pressure, slurry flow rate, conditioner rotation number, conditioner pressure, and polishing time are set.

In this embodiment, a table in which the relationship between wire perimeter and overpolishing process polishing rate is input is created and the wire perimeter and overpolishing process polishing rate are input in the table in Step 401.

Any one entry in the table is defined as a standard value and standard polishing times at the time of creation of recipe are calculated in Step 402. It goes without saying that the standard polishing time can be calculated by dividing the target polishing film thickness by the polishing rate for the standard wire perimeter.

In addition to the platen rotation number, polishing head rotation number, polishing head pressure, slurry flow rate, conditioner rotation number, and conditioner pressure, the standard wire perimeter and standard polishing time are input to create a recipe for the standard polishing condition in Step 403.

In Step 404 (calculation step), for processing a product type/layer that does not have a standard wire perimeter, the wire perimeter is input at the start of processing to automatically calculate the polishing time based on the table created in Step 401. For example, the calculation is performed as follows. The polishing time of a layer having any wire perimeter L is calculated by dividing the target polishing film thickness by the polishing rate for the wire perimeter L. The polishing rate for the wire perimeter L is obtained from the table.

In this embodiment, a table in which the relationship between wire perimeter and overpolishing process polishing rate is input is created in Step 401 and the polishing rate for the wire perimeter L is obtained from the table. However, the polishing rate can be calculated using an approximate line Y=aX+b wherein the wire perimeter is plotted on the X-axis and the overpolishing process polishing rate is plotted on the Y-axis as shown in FIG. 3.

Wafer processing starts in Step 405.

In this embodiment, the polishing time of the overpolishing can property be adjusted among the product types/layers and the differences in the overpolishing film thickness among the product types/layers can be reduced. The fact that the overpolishing film thickness can be controlled consistently regardless of the product types/layers yields not only its own efficacy but also efficacy that the metal film on the surface of the wafer W1 can always be removed completely and the Cu wiring having a uniform thickness allows for consistent control over the wiring resistance.

In Embodiment 1, the removal of barrier metal and adhesion layer on the surface of the wafer W1 can be detected by a known technique, for example by illuminating the wafer surface with a laser and detecting changes in the reflection intensity. However, because the devices are increasingly downsized, the removal of barrier metal and adhesion layer on the surface of the wafer W1 may not be detected by any prior art techniques. In such a case, the process time for removing the barrier metal and adhesion layer can be controlled in a similar manner as the method described this embodiment. In other words, the process time sufficient for removing the barrier metal is calculated based on the area and thickness of the barrier metal on the surface of the wafer W1 in Step 401. Similarly, the process time sufficient for removing the adhesion layer is calculated based on the area and thickness of the adhesion layer in Step 401.

### Embodiment 2

Embodiment 1 provides a method of automatically calculating the polishing time according to the wire perimeter and reflecting it in the recipe to perform the process for a proper polishing time. However, product types are changed in small lots frequently for improvement in the process capability index in high-mix low-volume production. It is significantly cumbersome to input the wire perimeter to the substrate polishing apparatus and calculate the polishing time at any given time.

Furthermore, changes in the conditions of components such as polishing pads and conditioners successively alter the polishing rate. As a method for controlling such alterations in the polishing rate resulting from changes in the conditions of the components, an APC (advanced process control) system is used to calculate the polishing time. The APC system is a technique for regularly measuring the processing results of processes and controlling the processes using the obtained data in fields involving many complex processes and a variety of variables.

In Embodiment 2, an APC system using the wire perimeter described in Embodiment 1 is described relative to a semiconductor mass production process in which the progress of lots is controlled by an MES (manufacturing execution system).

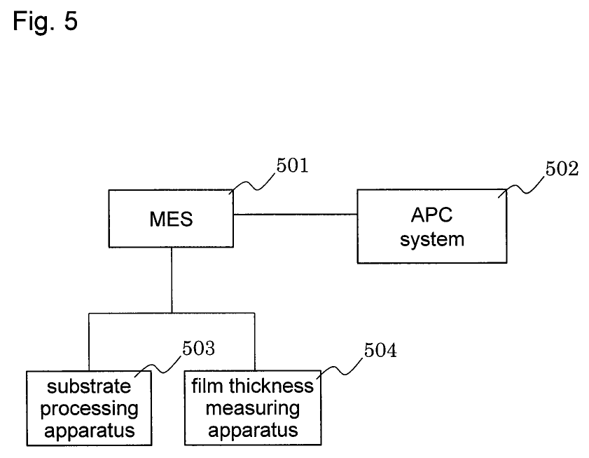

FIG. 5 shows a process control system configuration of Embodiment 2. An MES 501 is a system for controlling the progress of product lots in a semiconductor plant, administrating and controlling in which apparatus product lots are processed. An APC system 502 performs an APC calculation step in which the polishing time is calculated for a substrate processing apparatus 503. A film thickness measuring apparatus 504 measures the film thickness of product wafers.

The components 501 to 504 are networked as shown by solid lines in FIG. 5. Data are exchanged via network communication.

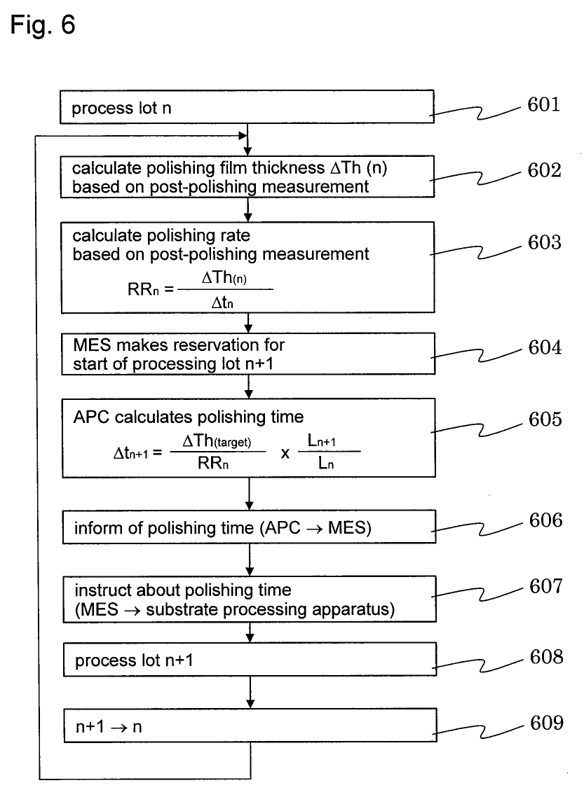

FIG. 6 shows a flowchart of the production process using an APC system of Embodiment 2.

First, the substrate processing apparatus 503 polishes multiple wafers in a lot n for an overpolishing time of Δt (n) among multiple lots each consisting of multiple wafers in Step 601.

The overpolishing film thickness ΔTh (n) resulting from the overpolishing is obtained in Step 602. This can be done by the film thickness measuring apparatus 504 or an in-line film thickness measuring instrument provided to the substrate processing apparatus 503.

Then, the polishing rate RR (n) is obtained based on the overpolishing film thickness ΔTh (n) in Step 603. Here, the polishing rate RR (n) is obtained using the following relational expression (1):

RR(n)=(ΔTh(n)/Δt(n)) (1)

Then, the MES 501 makes a reservation for the start of processing a lot n+1 in Step 604.

Then, triggered by the reservation information by the MES 501, the APC system 502 obtains a polishing time Δt (n+1) for processing the lot in Step 605 (APC calculation step). The polishing time Δt (n+1) is obtained using the following relational expression (2):

Δt(n+1)=(ΔTh(target)/RR(n))×(Lₙ₊₁/Lₙ) (2)

wherein Lₙ is the wire perimeter of layers processed in the lot n, Lₙ₊₁ is the wire perimeter of layers to be processed in the lot n+1, and ΔTh (target) is the target polishing film thickness.

Then, the APC system 502 provides notification to the MES 501 of the polishing time Δt (n+1) for the lot n+1 calculated using the relational expression (2) in Step 606.

The MES 501 instructs the substrate processing apparatus 503 about the polishing time Δt (n+1) in Step 607, after which the substrate processing apparatus 503 processes the lot n+1 with the polishing time Δt (n+1) in Step 608.

Then, n is replaced with n+1 in Step 609 and the process from Step 602 to Step 609 is repeated to process all lots by CMP.

After maintenance services such as replacement of polishing pads or conditioners (n=0), the process from Step 601 to Step 609 is performed using the polishing rate calculated in polishing a blanket wafer after the maintenance service.

As described above, with the overpolishing time after the removal of barrier metal in Cu-CMP being calculated according to the flowchart shown in FIG. 6, the polishing film thickness can be controlled with accuracy while taking into consideration not only successive changes in the equipment characteristics of the CMP apparatus but also differences among the product types/layers.

Advantageously, the number of recipes in the apparatus can be reduced compared with Embodiment 1, facilitating the recipe administration.

### Embodiment 3

An embodiment of an APC system using the wire perimeter in a semiconductor mass production plant in which the progress of lots is controlled by an MES system is described in Embodiment 2. The film thickness has to be measured to execute the APC system in Embodiment 2. More measurement of the film thickness leads to increase in semiconductor production cost (increase in measurement cost).

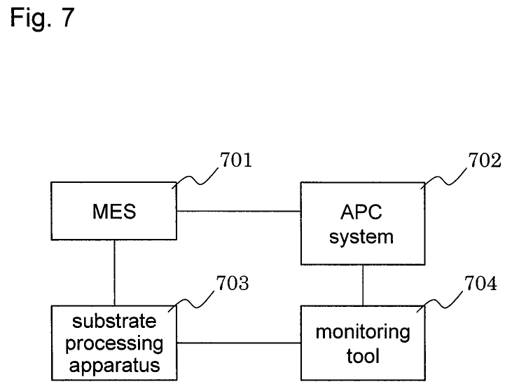

Then, a method to reduce the film thickness measurement is described in Embodiment 3. FIG. 7 shows a process control system configuration of Embodiment 3.

In FIG. 7, an MES 701 is a system for controlling the progress of production lots in a semiconductor plant, administrating and controlling in which apparatus production lots are processed.

An APC system 702 executes an APC calculation step in which the polishing time is calculated for a substrate processing apparatus 703. A monitoring tool 704 obtains process parameters from the substrate processing apparatus 703 in real time.

The components 701 to 704 are networked as shown by solid lines in FIG. 7. Data are exchanged via network communication.

The monitoring tool 704 obtains process parameters, particularly platen rotation torque currents from the substrate polishing apparatus 703 in real time while processing product wafers. The platen rotation torque current is presumably an indirect measurement of the contact state between the polishing pad and wafer.

Changes in the conditions of polishing pads and conditioners alter the friction between the polishing pad and wafer and, then, fluctuates the friction torque. Monitoring the current value of a polishing turntable drive motor, fluctuations in the friction torque can presumably be gauged as fluctuations in the load torque.

Therefore, the platen rotation torque current value presumably correlates with the polishing rate.

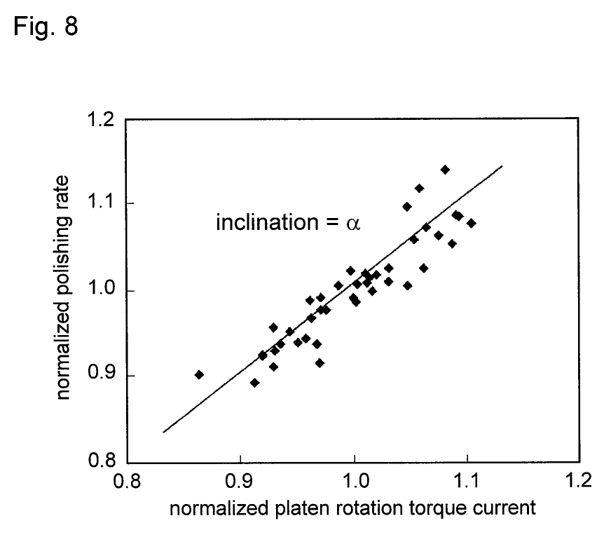

FIG. 8 shows the relationship between platen rotation torque current value and polishing rate. In FIG. 8, the ordinate and abscissa have normalized scales. It is understood from FIG. 8 that the platen rotation torque current and polishing rate correlate with each other. Here, the polishing rates were obtained in polishing wafers of various product types/layers having standard wire perimeters as defined in Step 402 of FIG. 4. A flowchart used with the APC system in which the polishing rate estimated from the platen rotation torque current obtained from the monitoring tool is calculated based on the relationship shown in FIG. 8 in real time is given.

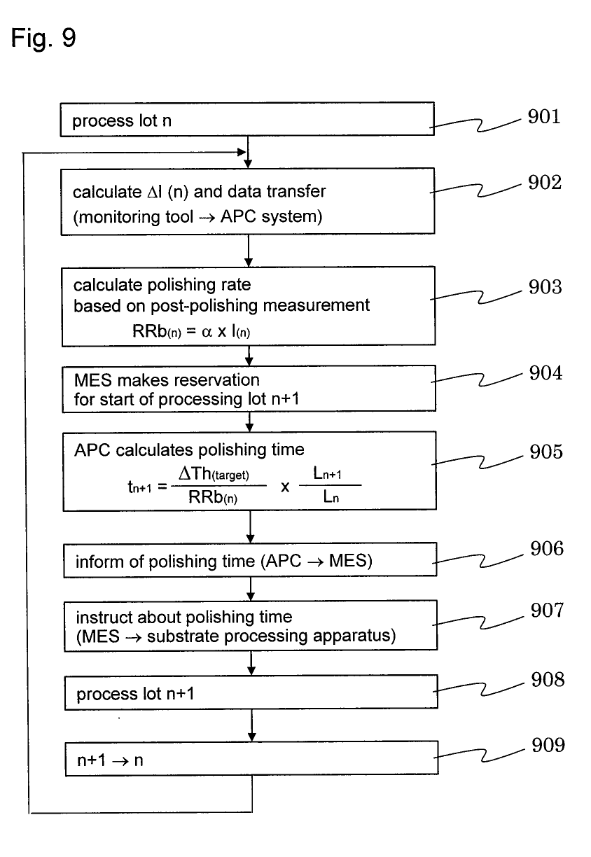

FIG. 9 shows a flowchart of the production method using an APC system of Embodiment 3.

First, the substrate processing apparatus 703 polishes multiple wafers in a lot n for an overpolishing time of Δt (n) among multiple lots each consisting of multiple wafers in Step 901.

Then, the monitoring tool 704 provides notification to the APC system of a platen rotation torque current I (n) during the processing of the lot n in Step 902.

Then, the APC system 903 obtains a polishing rate RRb (n) from the platen rotation torque current I (n) in process. The polishing rate RRb (n) is obtained using the following relational expression (3).

RRb=α×I(n) (3)

wherein α is the inclination of the graph shown in FIG. 8.

Then, the MES 701 makes a reservation for the start of processing a lot n+1 in Step 904.

Then, triggered by the reservation information by the MES 701, the APC system 702 obtains a polishing time Δt (n+1) for processing the lot in Step 905 (APC calculation step). The polishing time Δt (n+1) is obtained using the following relational expression (4):

Δt(n+1)=(ΔTh(target)/RRb(n))×(Lₙ₊₁/Lₙ) (4)

wherein Lₙ is the wire perimeter of layers processed in the lot n, Lₙ₊₁ is the wire perimeter of layers to be processed in the lot n+1, and ΔTh (target) is the target polishing film thickness.

Then, the APC system 702 provides notification to the MES 701 of the polishing time Δt (n+1) for the lot n+1 calculated using the relational expression (4) in Step 606.

Then, the MES 701 instructs the apparatus about the polishing time Δt (n+1) in Step 907.

Then, the substrate processing apparatus 703 processes the lot n+1 with the polishing time Δt (n+1) in Step 908.

Then, n is replaced with n+1 in Step 909 and the process from Step 902 to Step 909 is repeated to process all lots by CMP.

Hence, it is unnecessary to measure the film thickness when an APC system is used to calculate the overpolishing time after the removal of barrier metal in Cu-CMP according to the flowchart in FIG. 9, reducing production cost compared with Embodiment 2.

As described above, the present invention provides a useful substrate processing method, having the efficacy that Cu wirings having a uniform thickness allows for consistent control over the wire resistance, realizing high yields.

What is claimed is:

1. A semiconductor device production method for forming wirings using copper wiring materials, characterized by comprising:
a polishing step in which overpolishing after the removal of barrier metal is performed by chemical mechanical polishing; and
a calculation step in which the polishing time is calculated based on the wire perimeter on the surface to be polished of a semiconductor wafer.

2. The semiconductor device production method according to claim 1 wherein said calculation step is an APC system calculation step in which an APC (advanced process control) system is used to calculate the polishing time.

3. A semiconductor device production method for forming wirings using copper wiring materials, characterized by comprising
a polishing step in which overpolishing after the removal of barrier metal is performed by chemical mechanical polishing; and
an APC system calculation step in which an APC (advanced process control) system is used to calculate the polishing time by estimating the polishing rate from monitoring data obtained from the substrate processing apparatus in real time.

4. The semiconductor device production method according to claim 3 wherein said APC system calculation step is a step of calculating the polishing time based on the wire perimeter on the surface to be polished of a semiconductor wafer.
